(19) United States
(12) Patent Application Publication
(10) Pub. No.: US 2010/0109613 A1
(43) Pub. Date: May 6, 2010

(54) Switch control circuit with voltage sensing function and camera flash capacitor charger thereof

(76) Inventors: Yung-Chun Chuang, Taipei City (TW); Yu-Min Sun, Taipei County (TW); Chien-Chuan Chung, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/344,277

(22) Filed: Dec. 25, 2008

(30) Foreign Application Priority Data
Nov. 3, 2008 (TW) 097142342

(51) Int. Cl. H02J 7/00; H03K 17/56

(52) U.S. Cl. 320/166; 327/419

(57) ABSTRACT

A switch control circuit has a voltage sensing function. The switch control circuit includes a voltage-clamping buffer, a set driver, a reset driver, and an R-dominant SR latch. The voltage-clamping buffer shifts a switch voltage to generate a down-shifted switch voltage. The set driver generates a set signal according to the down-shifted switch voltage. The reset driver generates a reset signal according to the down-shifted switch voltage. The R-dominant SR latch comprises a set end for receiving the set signal, a reset end for receiving the reset signal, an output end for outputting a switch control signal for controlling conductance of a first transistor coupled to a primary winding of a transformer, and an output bar end for outputting an inverted switch control signal.

### BACKGROUND OF THE INVENTION

1. Field of the Invention

The present invention relates to flash capacitor chargers, and more particularly to a flash capacitor charger with a voltage sensing function.

2. Description of the Prior Art

Please refer to FIG. 1, which is a diagram of a camera flash capacitor charger 1 00 according to the prior art. As shown in FIG. 1, the camera flash capacitor charger 100 comprises a transformer 110, a switch control circuit 120, a comparator CMP₁, two feedback resistors R_{FB1}, R_{FB2}, a diode D₁, a transistor M₁, and an output capacitor C_{OUT}. The camera flash capacitor charger 100 is utilized for increasing an input voltage source V_{DD} (outputs the voltage V_{DD}) to generate an output voltage source V_{OUT} (outputs the voltage V_{OUT}), which is utilized for providing voltage needed for a camera flash unit to flash.

Generally speaking, the output voltage V_{OUT} should be approximately 300V in order to make the camera flash unit flash. However, as the input voltage source V_{DD} is typically provided by a battery, the voltage V_{DD} is around 5V. Thus, the camera flash capacitor charger 100 increases the 5 Volts of the voltage source V_{DD} to 300V to allow the camera flash unit to flash. Besides, the voltage source V_{SS} may be seen as ground.

The transformer 110 includes a primary winding 111 and a secondary winding 112. The primary winding 111 is coupled to the voltage source V_{DD} and the transistor M₁. The secondary winding 112 is coupled to the output voltage source V_{OUT} and the voltage source V_{SS}. More particularly, the secondary winding 112 is connected to the output voltage source V_{OUT} through the diode D₁.

The transistor M₁ is an N-channel Metal Oxide Semiconductor (NMOS) transistor, and is coupled to the primary winding 111 and the voltage source V_{SS}. When the transistor M₁ is turned on, the primary winding 111 is connected to the voltage source V_{SS} through the transistor M₁, such that a current I is generated by the voltage source V_{DD} for charging the primary winding 111; when the transistor M₁ is turned off, the current I built up in the primary winding 111 begins to discharge through the secondary winding 112 to charge the output capacitor C_{OUT} through the diode D₁. Through this charge/discharge mechanism, the output voltage V_{OUT} is steadily increased to the required voltage, e.g. 300V.

The feedback resistors R_{FB1}, R_{FB2} are coupled to the diode D₁ and the voltage source V_{SS} for providing a feedback voltage V_{FB}, which is divided from the output voltage V_{OUT}.

The comparator CMP₁ compares a reference voltage V_{REF} and the feedback voltage V_{FB} for generating a switch enabling signal S_{EN} accordingly. The switch enabling signal S_{EN} has two levels, “enabled” and “disabled,” for controlling on/off status of the transistor M₁. More particularly, when the feedback voltage V_{FB} is lower than the reference voltage V_{REF}, the comparator CMP₁ outputs the switch enabling signal S_{EN} as enabled; when the feedback voltage V_{FB} is higher than the reference voltage V_{REF}, the comparator CMP₁ outputs the switch enabling signal S_{EN} as disabled.

The switch control circuit 120 is coupled to a source of the transistor M₁, a gate of the transistor M₁, and an output end of the comparator CMP₁. The switch control circuit 120 receives switch voltage V_{SW} through the source of the transistor M₁, and receives switch enabling signal S_{EN} through the comparator CMP₁. The switch control circuit 120 generates switch control signal S_{SW} according to the switch voltage V_{SW} and the switch enabling signal S_{EN}. More particularly, when the switch enabling signal S_{EN} indicates “enabled,” the switch control circuit 120 generates the switch control signal S_{SW} according to the switch voltage V_{SW}; when the switch enabling signal S_{EN} indicates “disabled,” the switch control circuit 120 does not generate the switch control signal S_{SW}, keeping the transistor M₁ in the off state, such that the primary winding 111 cannot be charged further.

Because the switch voltage V_{SW} is rapidly increased to a very high voltage level when the primary winding 111 begins to be discharged right after being charged, circuit elements of the switch control circuit 120 must be able to withstand high voltages. The switch control circuit 120 therefore requires components resistant to high voltages, increasing cost and reducing convenience.

### SUMMARY OF THE INVENTION

According to an embodiment of the present invention, a switch control circuit has a voltage sensing function. The switch control circuit is coupled to a control end of a first transistor. The first transistor comprises a first end, a second end, and the control end. The first end of the first transistor is coupled to a first end of a primary winding of a transformer, and the second end of the first transistor is coupled to a first source voltage. A second end of the primary winding of the transformer is coupled to a second source voltage. The switch control circuit comprises a voltage-clamping buffer, a set driver, a reset driver, and an R-dominant SR latch. The voltage-clamping buffer is coupled to the first end of the first transistor for receiving a switch voltage and shifting the switch voltage to generate a down-shifted switch voltage. The set driver is coupled to the voltage-clamping buffer for receiving the down-shifted switch voltage and generating a set signal according to the down-shifted switch voltage. The reset driver is coupled to the voltage-clamping buffer for receiving the down-shifted switch voltage and generating a reset signal according to the down-shifted switch voltage. The R-dominant SR latch comprises a set end coupled to the set driver for receiving the set signal, a reset end coupled to the reset driver for receiving the reset signal, an output end coupled to the control end of the first transistor for outputting a switch control signal to the control end for controlling conductance of the first transistor, and an output bar end for outputting an inverted switch control signal. The inverted switch control signal has logic level inverse the switch control signal. When the set signal is at a first logic level, the switch control signal is at the first logic level. When the reset signal is at the first logic level, the switch control signal is at a second logic level. When the set signal and the reset signal are simultaneously at the first logic level the switch control signal is at the second logic level. When the switch control signal is at the first logic level, the first transistor conducts to couple the primary winding to the first source voltage. When the switch control signal is at the second logic level, the first transistor does not conduct.

According to another embodiment, a flash capacitor charger has a voltage sensing function. The flash capacitor charger comprises a transformer, a diode, a first transistor, and a switch control circuit. The transformer comprises a primary winding and a secondary winding. The primary winding comprises a first end, and a second end coupled to a second source voltage. The secondary winding comprises a first end, and a second end coupled to a first source voltage. The diode is coupled to the first end of the secondary winding for outputting an output voltage. The first transistor comprises a first end coupled to the first end of the primary winding, a second end coupled to the first source voltage, and a control end for receiving a switch control signal. The switch control circuit comprises a voltage-clamping buffer, a set driver, a reset driver, and an R-dominant SR latch. The voltage-clamping buffer is coupled to the first end of the first transistor for receiving a switch voltage and shifting the switch voltage to generate a down-shifted switch voltage. The set driver is coupled to the voltage-clamping buffer for receiving the down-shifted switch voltage and generating a set signal according to the down-shifted switch voltage. The reset driver is coupled to the voltage-clamping buffer for receiving the down-shifted switch voltage and generating a reset signal according to the down-shifted switch voltage. The R-dominant SR latch comprises a set end coupled to the set driver for receiving the set signal, a reset end coupled to the reset driver for receiving the reset signal, an output end coupled to the control end of the first transistor for outputting a switch control signal to the control end for controlling conductance of the first transistor, and an output bar end for outputting an inverted switch control signal. The inverted switch control signal has logic level inverse the switch control signal. When the set signal is at a first logic level, the switch control signal is at the first logic level. When the reset signal is at the first logic level, the switch control signal is at a second logic level. When the set signal and the reset signal are simultaneously at the first logic level the switch control signal is at the second logic level. When the switch control signal is at the first logic level, the first transistor conducts to couple the primary winding to the first source voltage. When the switch control signal is at the second logic level, the first transistor does not conduct.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a camera flash capacitor charger according to the prior art.

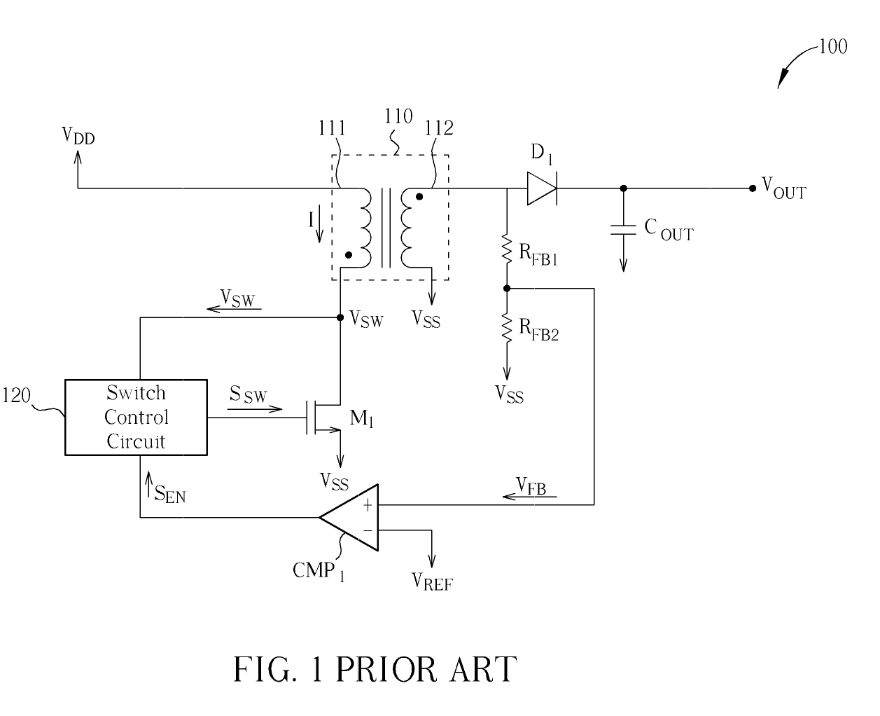

FIG. 2 is a diagram of a flash capacitor charger with a voltage sensing function according to an embodiment of the present invention.

FIG. 3 is a timing diagram of internal signals of the switch control circuit of the flash capacitor charger.

### DETAILED DESCRIPTION

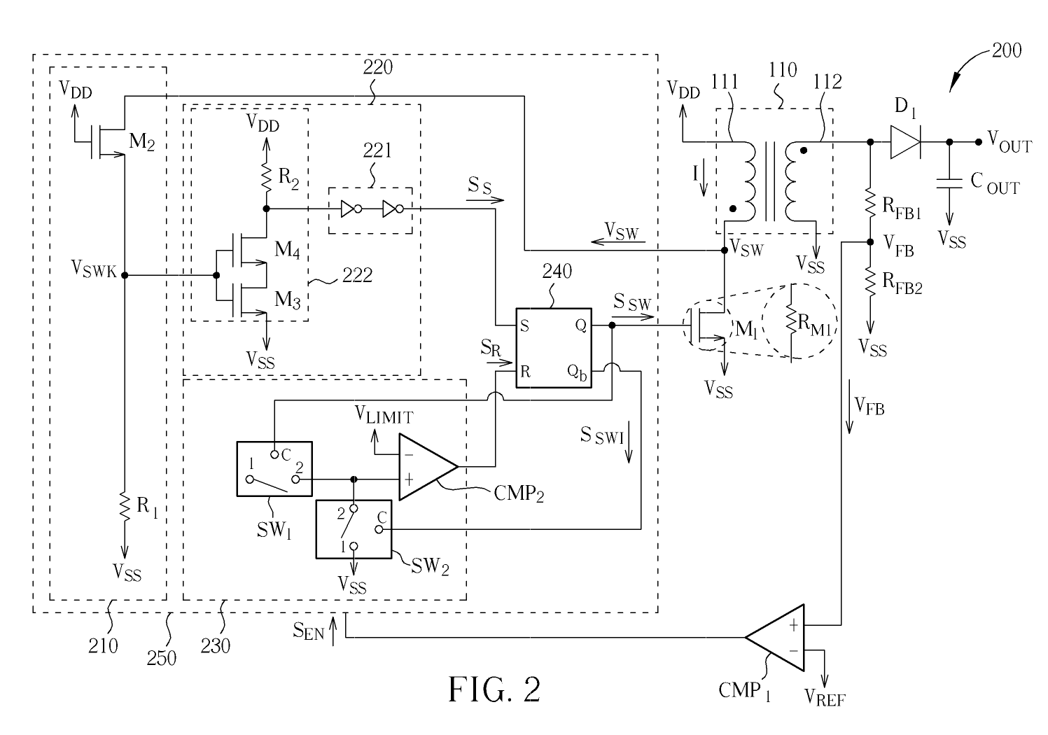

Please refer to FIG. 2, which is a diagram of a flash capacitor charger 200 with a voltage sensing function according to one embodiment. As shown in FIG. 2, the flash capacitor charger 200 has structure similar to the flash capacitor charger 100 of the prior art. However, the flash capacitor charger 200 comprises a switch control circuit 250 having structure different from the switch control circuit 120 of the prior art.

The switch control circuit 250 comprises a voltage-clamping buffer 210, a set driver 220, a reset driver 230, and an R-dominant SR latch 240.

Likewise, the switch control circuit 250 generates the switch control signal S_{SW} according to the switch voltage V_{SW} and the switch enabling signal S_{EN}. More particularly, when the switch enabling signal S_{EN} indicates “enabled,” the switch control circuit 250 generates the switch control signal S_{SW} according to the switch voltage V_{SW}; when the switch enable signal S_{EN} indicates “disabled,” the switch control circuit 250 does not generate the switch control signal S_{SW}, keeping the transistor M₁ in the off state, such that the primary winding 111 cannot be charged. Further, the switch control signal S_{SW} is a periodic signal.

The voltage-clamping buffer 210 comprises an NMOS transistor M₂ and a resistor R₁. The transistor M₂ may be a high-voltage-withstanding component.

A gate of the transistor M₂ is coupled to the voltage source V_{DD} for receiving the voltage V_{DD}; a drain of the transistor M₂ is coupled to the drain of the transistor M₁ (primary winding 111) for receiving the switch voltage V_{SW}; a source of the transistor M₂ is coupled to the resistor R₁ for outputting the down-shifted switch voltage V_{SWK}.

Because the gate of the transistor M₂ receives the voltage V_{DD}, the voltage level of the down-shifted switch voltage V_{SWK} has an upper limit clamped lower than the source voltage V_{DD} by the gate-source voltage V_{GS2} of the transistor M₂, i.e. V_{DD}-V_{GS2}. Thus, the down-shifted switch voltage V_{SWK} is not increased to the relatively high voltage level of the switch voltage V_{SW}. Thus, components performing later operations according to the voltage level of the down-shifted switch voltage V_{SWK} do not need to be high-voltage-withstanding components, which saves cost.

The set driver 220 comprises a waveform-shaping circuit 221 and a level-detecting circuit 222.

The level-detecting circuit 222 may be utilized for detecting voltage level of the down-shifted switch voltage V_{SWK}. When the down-shifted switch voltage V_{SWK} is lower than a predetermined voltage V_{P}, the level-detecting circuit 222 generates a logic high voltage (logic “1” voltage) acting as a set signal S_{S}. On the other hand, when the down-shifted switch voltage V_{SWK} is higher than the predetermined voltage V_{P}, the level-detecting circuit 222 generates a logic low voltage (logic “0” voltage) acting as the set signal S_{S}. The logic high voltage may be any voltage level above a logic high threshold, and the logic low voltage may be any voltage level below a logic low threshold. In one embodiment, for example, in a range of 0V-5V, the logic high threshold may be 4V, and the logic low threshold may be 1 V.

The level-detecting circuit 222 comprises a resistor R₂ and two NMOS transistors M₃ and M₄. The predetermined voltage V_{P} may be equal to the threshold voltage V_{TH} of NMOS transistors M₃ and M₄, namely V_{P}=V_{TH}. In addition, the level-detecting circuit 222 may also be realized with one resistor and one NMOS transistor. In this embodiment, the NMOS transistors M3 and M4 are in cascode for the purpose of reducing bulk effect and effectively increasing the equivalent threshold voltage V_{TH}.

When the down-shifted switch voltage V_{SWK} is lower than the predetermined voltage V_{P}, both of the transistors M₃ and M₄ are not turned on. Thus, the level-detecting circuit 222 utilizes the voltage V_{DD} to output the set signal S_{S} with the logic high voltage through the resistor R₂.

On the other hand, when the down-shifted switch voltage V_{SWK} is higher than the predetermined voltage V_{P}, the transistors M₃ and M₄ are turned on. Thus, the level-detecting circuit 222 utilizes the turned-on transistors M₃ and M₄ to couple to the voltage V_{SS} for outputting the set signal S_{S} with the logic low voltage.

However, the purpose of installing NMOS transistors in the level-detecting circuit 222 is only for utilizing the threshold voltage of the installed NMOS transistors to determine the voltage level of the down-shifted switch voltage V_{SWK}. Although two NMOS transistors are utilized in the level-detecting circuit 222 in the present embodiment, in another embodiment one NMOS transistor may be utilized. In another embodiment, a plurality of NMOS transistors may be utilized in the level-detecting circuit 222. In other words, number of NMOS transistors utilized in the level-detecting circuit 222 is not limited.

The waveform-shaping circuit 221 may be utilized for shaping the set signal S_{S} outputted from the level-detecting circuit 222 to have a waveform approaching a square waveform, so as to prevent the set signal S_{S} from having a level between the logic high threshold and the logic low threshold, i.e. a level that is neither logic high nor logic low. In other words, the waveform-shaping circuit 221 shaping the set signal S_{S} into a square waveform helps to prevent operation errors in the SR latch 240 based on the set signal S_{S}. As shown in FIG. 2, the waveform-shaping circuit 221 may be realized as two inverters connected in series.

In one embodiment, the R-dominant SR latch 240 comprises a set end S, a reset end R, an output end Q, and an output bar end Qb.

The set end S of the R-dominant SR latch 240 is coupled to the set driver 220 for receiving the set signal S_{S}; the reset end R of the R-dominant SR latch 240 is coupled to the reset driver 230 for receiving the reset signal S_{R}; the output end Q of the R-dominant SR latch 240 is coupled to the gate of the transistor M₁ for generating the switch control signal S_{SW} according to the set signal S_{S} and the reset signal S_{R} to control on/off state of the transistor M₁; the output bar end Qb of the R-dominant SR latch 240 outputs an inverted switch control signal S_{SWI}, which has logic level inverse of the switch control signal S_{SW}.

When the R-dominant SR latch 240 receives the set signal S_{S} with logic level “1,” the R-dominant SR latch 240 outputs the switch control signal S_{SW} with the logic high voltage (logic “1”) from the output end Q, and inverted switch control signal S_{SWI} with the logic low voltage (logic “0”) from the output bar end Qb.

When the R-dominant SR latch 240 receives the reset signal S_{R} with logic level “0,” the R-dominant SR latch 240 outputs the switch control signal S_{SW} with the logic low voltage (logic “0”) from the output end Q, and the inverted switch control signal S_{SWI} with the logic high voltage (logic “1”) from the output bar end Qb.

When the R-dominant SR latch 240 receives both the set signal S_{S} and the reset signal S_{R} with logic level “1,” the R-dominant SR latch 240 outputs the switch control signal S_{SW} with the logic low voltage (logic “0”) from the output end Q, and the inverted switch control signal S_{SWI} with the logic high voltage (logic “1”) from the output bar end Qb.

The reset driver 230 comprises a comparator CMP₂ and two switches SW₁ and SW₂.

The first end 1 of the switch SW₁ is coupled to the voltage-clamping buffer 210 for receiving the down-shifted switch voltage V_{SWK}; the second end 2 of the switch SW₁ is coupled to the positive input end of the comparator CMP₂; the control end C of the switch SW₁ is coupled to the output end Q of the R-dominant SR latch 240 for receiving the switch control signal S_{SW}.

When the switch control signal S_{SW} is at logic “1,” the first end 1 of the switch SW₁ is coupled to the second end 2 of the switch SW₁, so that the down-shifted switch voltage V_{SWK} is sent to the positive input end of the comparator CMP₂; when the switch control signal S_{SW} is at logic “0,” the first end 1 of the switch SW₁ is not coupled to the second end 2 of the switch SW₁, so that the down-shifted switch voltage V_{SWK} is not sent to the positive input end of the comparator CMP₂.

The first end 1 of the switch SW₂ is coupled to the voltage source V_{SS} (ground) for receiving the voltage V_{SS} (low voltage level); the second end 2 of the switch SW₂ is coupled to the positive input end of the comparator CMP₂; the control end C of the switch SW₂ is coupled to the output bar end Qb of the R-dominant SR latch 240 for receiving the inverted switch control signal S_{SWI}.

When the inverted switch control signal S_{SWI} is at logic “1,” the first end 1 of the switch SW₂ is coupled to the second end 2 of the switch SW₂, so that the voltage V_{SS} (low voltage level) is sent to the positive input end of the comparator CMP₂; when the inverted switch control signal S_{SWI} is at logic “0,” the first end 1 of the switch SW₂ is not coupled to the second end 2 of the switch SW₂, so that the voltage V_{SS} is not sent to the positive input end of the comparator CMP₂.

The negative input end of the comparator CMP₂ is utilized for receiving an upper threshold voltage V_{LIMIT}. The comparator CMP₂ compares voltage amplitudes on the positive input end and the negative input end, and outputs a comparison signal as the reset signal S_{R}. More specifically, when voltage on the positive input end of the comparator CMP₂ is greater than the upper threshold voltage V_{LIMIT}, the comparator CMP₂ outputs the reset signal S_{R} with logic “1.”

In summary, operation of the reset driver 230 may be understood as follows. When the switch control signal S_{SW} is at logic “1,” the transistor M₁ is turned on, and the voltage source V_{DD} begins to charge the primary winding 111 to generate the current I with steadily increasing amplitude. Because the transistor M₁ acts as an equivalent resistor R_{M1}, having a limit of drain-source resistance R_{DS}_{_{—}}_{ON} of the transistor M₁, when the transistor M₁ is turned on, the switch voltage V_{SW} increases with the increasing current I, as V_{SW}=R_{M1}×1. In other words, the down-shifted switch voltage V_{SWK} also increases with the increasing current I.

On the other hand, because the primary winding 111 of the transformer 110 has a current amplitude limit, if the current I increases without limit, the transformer 110 may be damaged. Thus, the reset driver 230 limits the current I.

Based on the above, amplitude of the current I is directly proportional to the down-shifted switch voltage V_{SWK}. Thus, when the transistor M₁ is turned on (the switch control signal S_{SW} is at logic “1”), the first end 1 of the switch SW₁ is coupled to the second end 2 of the switch SW₁ for sending the down-shifted switch voltage V_{SWK} to the positive input end of the comparator CMP₂. At this time, the comparator CMP₂ compares the down-shifted switch voltage V_{SWK} with the upper limit voltage V_{LIMIT}. When the down-shifted switch voltage V_{SWK} is greater than the upper limit voltage V_{LIMIT}, the current I flowing through the primary winding 111 has reached the upper limit. Thus, the transistor M₁ is turned off, and the comparator CMP₂ outputs the reset signal S_{R} at logic “1” to the R-dominant SR latch 240 for resetting the SR latch 240, namely resetting the switch control signal S_{SW} from logic “1” to logic “0.” By turning off the transistor M₁ at an appropriate time, the primary winding 111 is prevented from being damaged by the over-magnitude current I.

On the other hand, when the transistor M₁ is turned off (the inverted switch control signal S_{SWI} is at logic “1”), the first end 1 of the switch SW₂ is coupled to the second end 2 of the switch SW₂ for sending the voltage V_{SS} to the positive input end of the comparator CMP₂. Because the voltage V_{SS} is lower than the upper limit voltage V_{LIMIT}, at this time, the reset signal S_{R} outputted from the comparator CMP₂ is held at logic “0,” and does not reset the R-dominant SR latch 240.

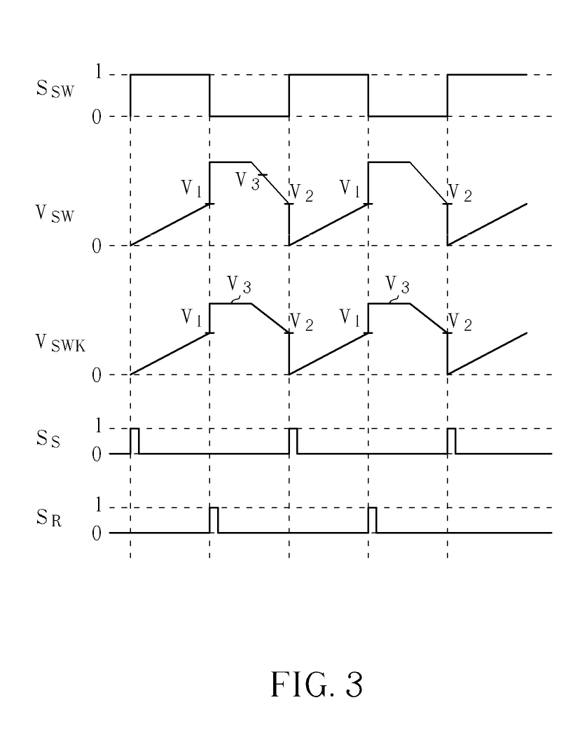

Please refer to FIG. 3, which is a timing diagram of internal signals of the switch control circuit 250 of the flash capacitor charger 200 having a voltage sensing function according to an embodiment of the present invention. As shown in FIG. 3, the voltage V₁ represents the upper limit voltage V_{LIMIT}, the voltage V₂ represents the threshold voltage V_{TH} of the transistors M₃ and M₄, and the voltage V₃ represents (V_{DD}-V_{GS2}). As can be seen from FIG. 3, when the down-shifted switch voltage V_{SWK} reaches the upper limit voltage V_{LIMIT}, the reset signal S_{R} goes to logic “1” to reset the R-dominant SR latch 240, such that the switch control signal S_{SW} transitions to logic “0” to turn off the transistor M₁, thereby increasing the switch voltage V_{SW} abruptly. Likewise, the down-shifted switch voltage V_{SWK} also increases abruptly. However, due to the voltage-clamping buffer 210, the down-shifted switch voltage V_{SWK} only increases to (V_{DD}-V_{GS2}), and is not increased to the amplitude as high as the switch voltage V_{SW}. After the transistor M₁ is turned off, the primary winding 111 begins discharging, and the current I drops steadily. In other words, the switch voltage V_{SW} and the down-shifted switch voltage V_{SWK} also drop steadily. When the down-shifted switch voltage V_{SWK} drops lower than the voltage V₂, the transistors M₃ and M₄ of the level-detecting circuit 222 are turned off, the set signal S_{S} is increased to logic “1” and sent to the R-dominant SR latch 240 to transition the switch control signal S_{SW} from logic “0” to logic “1,” so as to turn on the transistor M₁ again, and reinitiate charging of the primary winding 111. This cycle allows the output voltage V_{OUT} to increase steadily to the required voltage level, e.g. 300V. When the output voltage V_{OUT} reaches the required voltage level, the comparator CMP₁ outputs the switch enabling signal S_{EN} as “disabled” to the switch control circuit 250 to disable operation of the switch control circuit 250.

The switch control circuit and the flash capacitor charger described in the above embodiments effectively sense voltage to prevent damage to the winding of the transformer, and effectively remove the need for components resistant to high voltages, increasing convenience to the user.

Those skilled in the art will readily observe that numerous modifications and alterations of the device and method may be made while retaining the teachings of the invention.

What is claimed is:

1. A switch control circuit with a voltage sensing function, the switch control circuit coupled to a control end of a first transistor, the first transistor comprising a first end, a second end, and the control end, the first end of the first transistor coupled to a first end of a primary winding of a transformer, the second end of the first transistor coupled to a first source voltage, a second end of the primary winding of the transformer coupled to a second source voltage, the switch control circuit comprising:
a voltage-clamping buffer coupled to the first end of the first transistor for receiving a switch voltage and shifting the switch voltage to generate a down-shifted switch voltage;
a set driver coupled to the voltage-clamping buffer for receiving the down-shifted switch voltage and generating a set signal according to the down-shifted switch voltage;
a reset driver coupled to the voltage-clamping buffer for receiving the down-shifted switch voltage and generating a reset signal according to the down-shifted switch voltage; and
an R-dominant SR latch comprising:
a set end coupled to the set driver for receiving the set signal;
a reset end coupled to the reset driver for receiving the reset signal;
an output end coupled to the control end of the first transistor for outputting a switch control signal to the control end for controlling conductance of the first transistor; and
an output bar end for outputting an inverted switch control signal;
wherein the inverted switch control signal has logic level inverse the switch control signal;
wherein when the set signal is at a first logic level, the switch control signal is at the first logic level;
wherein when the reset signal is at the first logic level, the switch control signal is at a second logic level;
wherein when the set signal and the reset signal are simultaneously at the first logic level the switch control signal is at the second logic level;
wherein when the switch control signal is at the first logic level, the first transistor conducts to couple the primary winding to the first source voltage;
wherein when the switch control signal is at the second logic level, the first transistor does not conduct.

2. The switch control circuit of claim 1, wherein the first source voltage is a ground end.

3. The switch control circuit of claim 2, wherein the voltage-clamping buffer comprises:
a second transistor comprising:
a first end coupled to the first end of the first transistor;
a second end for outputting the down-shifted switch voltage; and
a control end coupled to the second supply voltage; and
a first resistor coupled to the second end of the second transistor and the first source voltage.

4. The switch control circuit of claim 3, wherein the first transistor and the second transistor are N-channel Metal Oxide Semiconductor (NMOS) transistors.

5. The switch control circuit of claim 4, wherein the set driver comprises:
a level detecting circuit coupled to the second end of the second transistor for receiving the down-shifted switch voltage and generating the set signal according to voltage level of the down-shifted switch voltage.

6. The switch control circuit of claim 5, wherein the level detecting circuit comprises:
a third transistor comprising:
a first end coupled to the first supply voltage;
a control end coupled to the second end of the second transistor for receiving the down-shifted switch voltage; and
a second end;
wherein when voltage level of the down-shifted switch voltage is greater than threshold voltage of the third transistor, the first end of the third transistor couples to the second end of the third transistor; and
a resistor comprising:
a first end coupled to the second supply voltage; and
a second end coupled to the second end of the third transistor for outputting the set signal.

7. The switch control circuit of claim 6, wherein the third transistor is an NMOS transistor.

8. The switch control circuit of claim 6, wherein the set driver further comprises:
a waveform-shaping circuit coupled to the second end of the resistor and the set end of the SR latch for shaping waveform of the set signal.

9. The switch control circuit of claim 8, wherein the waveform-shaping circuit comprises:
a first inverter comprising:
an input end coupled to the second end of the resistor; and
an output end;
wherein output at the output end of the first inverter is inverse of input received by the input end of the first inverter; and
a second inverter comprising:
an input end coupled to the output end of the first inverter; and
an output end;
wherein the output end of the second inverter outputs the set signal as inverse of input received by the input end of the second inverter.

10. The switch control circuit of claim 4, wherein the reset driver circuit comprises:
a first switch comprising:
a first end coupled to the second end of the second transistor for receiving the down-shifted switch voltage;
a second end; and
a control end coupled to the output end of the SR latch for receiving the switch control signal;
wherein when the switch control signal is at the first logic level, the first end of the first switch couples to the second end of the first switch;
a second switch comprising:
a first end coupled to the first source voltage for receiving the down-shifted switch voltage;
a second end coupled to the second end of the first switch; and
a control end coupled to the output bar end of the SR latch for receiving the inverted switch control signal;
wherein when the inverted switch control signal is at the first logic level, the first end of the first switch couples to the second end of the first switch; and
a comparator comprising:
a positive input end coupled to the second end of the first switch;
a negative input end for receiving an upper limit voltage; and
an output end coupled to the reset end of the SR latch for outputting the reset signal;
wherein when voltage received at the positive input end of the comparator is higher than the upper limit voltage, the comparator outputs the reset signal at the first logic level.

11. A flash capacitor charger with a voltage sensing function, the flash capacitor charger comprising:
a transformer comprising:
a primary winding comprising:
a first end; and
a second end coupled to a second source voltage; and
a secondary winding comprising:
a first end; and
a second end coupled to a first source voltage;
a diode coupled to the first end of the secondary winding for outputting
an output voltage;
a first transistor comprising:
a first end coupled to the first end of the primary winding;
a second end coupled to the first source voltage; and
a control end for receiving a switch control signal; and
a switch control circuit comprising:
a voltage-clamping buffer coupled to the first end of the first transistor for receiving a switch voltage and shifting the switch voltage to generate a down-shifted switch voltage;
a set driver coupled to the voltage-clamping buffer for receiving the down-shifted switch voltage and generating a set signal according to the down-shifted switch voltage;
a reset driver coupled to the voltage-clamping buffer for receiving the down-shifted switch voltage and generating a reset signal according to the down-shifted switch voltage; and
an R-dominant SR latch comprising:
a set end coupled to the set driver for receiving the set signal;
a reset end coupled to the reset driver for receiving the reset signal;
an output end coupled to the control end of the first transistor for outputting a switch control signal to the control end for controlling conductance of the first transistor; and
an output bar end for outputting an inverted switch control signal;
wherein the inverted switch control signal has logic level inverse the switch control signal;
wherein when the set signal is at a first logic level, the switch control signal is at the first logic level;
wherein when the reset signal is at the first logic level, the switch control signal is at a second logic level;
wherein when the set signal and the reset signal are simultaneously at the first logic level the switch control signal is at the second logic level;
wherein when the switch control signal is at the first logic level, the first transistor conducts to couple the primary winding to the first source voltage;
wherein when the switch control signal is at the second logic level, the first transistor does not conduct.

12. The flash capacitor charger of claim 11, wherein the first source voltage is a ground end.

13. The flash capacitor charger of claim 12, wherein the Page 22 of 28 voltage-clamping buffer comprises:
a second transistor comprising:
a first end coupled to the first end of the first transistor;
a second end for outputting the down-shifted switch voltage; and
a control end coupled to the second supply voltage; and
a first resistor coupled to the second end of the second transistor and the first source voltage.

14. The flash capacitor charger of claim 13, wherein the first transistor and the second transistor are N-channel Metal Oxide Semiconductor (NMOS) transistors.

15. The flash capacitor charger of claim 14, wherein the set driver comprises:
a level detection circuit coupled to the second end of the second transistor for receiving the down-shifted switch voltage and generating the set signal according to voltage level of the down-shifted switch voltage.

16. The flash capacitor charger of claim 15, wherein the level detection circuit comprises:
a third transistor comprising:
a first end coupled to the first supply voltage;
a control end coupled to the second end of the second transistor for receiving the down-shifted switch voltage; and
a second end;
wherein when voltage level of the down-shifted switch voltage is greater than threshold voltage of the third transistor, the first end of the third transistor couples to the second end of the third transistor; and
a resistor comprising:
a first end coupled to the second supply voltage; and
a second end coupled to the second end of the third transistor for outputting the set signal.

17. The flash capacitor charger of claim 16, wherein the third transistor is an NMOS transistor.

18. The flash capacitor charger of claim 16, wherein the set driver further comprises:
a waveform-shaping circuit coupled to the second end of the resistor and the set end of the SR latch for shaping waveform of the set signal.

19. The flash capacitor charger of claim 18, wherein the waveform-shaping circuit comprises:
a first inverter comprising:
an input end coupled to the second end of the resistor; and
an output end;
wherein output at the output end of the first inverter is inverse of input received by the input end of the first inverter; and
a second inverter comprising:
an input end coupled to the output end of the first inverter; and
an output end;
wherein the output end of the second inverter outputs the set signal as inverse of input received by the input end of the second inverter.

20. The switch control circuit of claim 14, wherein the reset driver comprises:
a first switch comprising:
a first end coupled to the second end of the second transistor for receiving the down-shifted switch voltage;
a second end; and
a control end coupled to the output end of the SR latch for receiving the switch control signal;
wherein when the switch control signal is at the first logic level, the first end of the first switch couples to the second end of the first switch;
a second switch comprising:
a first end coupled to the first source voltage for receiving the down-shifted switch voltage;
a second end coupled to the second end of the first switch; and
a control end coupled to the output bar end of the SR latch for receiving the inverted switch control signal;
wherein when the inverted switch control signal is at the first logic level, the first end of the first switch couples to the second end of the first switch; and
a comparator comprising:
a positive input end coupled to the second end of the first switch;
a negative input end for receiving an upper limit voltage; and
an output end coupled to the reset end of the SR latch for outputting the reset signal;
wherein when voltage received at the positive input end of the comparator is higher than the upper limit voltage, the comparator outputs the reset signal at the first logic level.

21. The switch control circuit of claim 11, further comprising:
an output capacitor coupled to a negative end of the diode and the first source voltage for holding amplitude of the output voltage;
a first feedback resistor comprising:
a first end coupled to the negative end of the diode; and
a second end for outputting a feedback voltage;
a second feedback resistor comprising:
a first end coupled to the second end of the first feedback resistor; and
a second end coupled to the first source voltage; and
a second comparator comprising:
a positive input end coupled to the second end of the first feedback resistor for receiving the feedback voltage;
a negative input end for receiving a reference voltage; and
an output end coupled to the switch control circuit for outputting a switch enable signal;
wherein when voltage received at the positive input end of the second comparator is higher than the reference voltage, the switch enable signal stops enabling the switch control circuit.
